(19) United States
(12) Patent Application Publication
(10) Pub. No.: US 2026/0173346 A1
(43) Pub. Date: Jun. 18, 2026

(54) THREE-DIMENSIONAL DYNAMIC RANDOM ACCESS MEMORY

(71) Applicant: INSTITUTE OF MICROELECTRONICS, CHINESE ACADEMY OF SCIENCES, Beijing (CN)

(72) Inventors: Guanhua YANG, Beijing (CN); Xuanming ZHANG, Beijing (CN); Fuxi LIAO, Beijing (CN); Ling LI, Beijing (CN)

(73) Assignee: INSTITUTE OF MICROELECTRONICS, CHINESE ACADEMY OF SCIENCES, Beijing (CN)

(21) Appl. No.: 19/530,751

(22) Filed: Feb. 5, 2026

Related U.S. Application Data
(63) Continuation of application No. PCT/CN2025/088756, filed on Apr. 14, 2025.

(30) Foreign Application Priority Data
Oct. 22, 2024 (CN) 202411482419.5

(51) Int. Cl. H10B 12/00

(52) U.S. Cl. CPC H10B 12/30

(57) ABSTRACT

Provided is a three-dimensional dynamic random access memory, relating to the technical field of memory. The three-dimensional dynamic random access memory includes a plurality of memory cells arranged in a three-dimensional array and a dielectric structure configured to isolate the memory cells. Each memory cell includes a transistor and a capacitor. The transistor includes a gate, a gate dielectric layer, a channel region, a source region, and a drain region; a length direction of the channel region is parallel to a second direction, and two sidewalls of the channel region along the length direction are recessed inward relative to sidewalls of a corresponding first dielectric portion to form a notch. The source region and the drain region cover inner walls of the notch.

### CROSS REFERENCE TO RELATED APPLICATION

This application claims priority to Chinese Patent Application No. 202411482419.5, filed with the China National Intellectual Property Administration (CNIPA) on Oct. 22, 2024 and entitled “THREE-DIMENSIONAL DYNAMIC RANDOM ACCESS MEMORY AND MANUFACTURING METHOD THEREOF”, which is incorporated herein by reference in its entirety.

### TECHNICAL FIELD

The present disclosure relates to the technical field of memories, and in particular, to a three-dimensional dynamic random access memory (3D DRAM) and a manufacturing method thereof.

### BACKGROUND

In computer systems, the memory is a critical component for storing data and programs. The dynamic random access memory (DRAM), as an important type of memory, plays a key role in modern computer architectures. The DRAM includes a one-transistor-one-capacitor (1T1C) memory cell structure. Each memory cell of such DRAM includes one transistor and one capacitor connected to the source or drain of the transistor. The capacitor is used to store charge, and the transistor is used to control access to the capacitor. Such DRAM also includes word lines connected to the gates of the transistors and bit lines connected to the source or drain regions of the transistors. During access to data in a particular memory cell, the word line connected to the memory cell is selected, and a voltage that turns on the transistor is applied to the word line, to turn on the transistor. Then, the bit line connected to the memory cell is selected, thereby completing the selection of the memory cell and allowing access to the charge in the capacitor. However, since the capacitor gradually leaks electricity, leading to a decrease in stored charge, DRAM requires regular refresh (typically every few milliseconds) to maintain data validity. The refresh operation reads data in each memory cell and rewrites the data, thereby replenishing the charge lost from each capacitor.

In the prior art, memory cells of DRAM are arranged in an array along the horizontal direction of the wafer, which is known as two-dimensional dynamic random access memory (2D DRAM). However, the development of computer systems has imposed higher requirements on the density of DRAM, and the density of 2D DRAM is limited by process constraints and cannot meet the density requirements.

### SUMMARY

The present disclosure provides a 3D DRAM and a manufacturing method thereof, aiming to improve the storage density of DRAM, increase the contact areas of the source region and the drain region of a transistor with a contact structure or a capacitor, reduce contact resistance, and mitigate leakage current.

To achieve the foregoing objective, according to a first aspect, the present disclosure provides a 3D DRAM, which includes a plurality of memory cells arranged in a three-dimensional array, and a dielectric structure configured to isolate the plurality of the memory cells. The plurality of memory cells arranged in the three-dimensional array include a plurality of memory layers spaced apart along a first direction, each of the memory layers includes a plurality of memory groups spaced apart along a second direction, and each of the memory groups comprises a plurality of the memory cells distributed along a third direction. The first direction, the second direction, and the third direction are different from each other. Each of the memory cells includes a transistor and a capacitor. The dielectric structure includes first dielectric portions respectively located between adjacent ones of the transistors spaced apart along the first direction. The transistor includes: a gate, a gate dielectric layer, a channel region, a source region, and a drain region. A length direction of the channel region is parallel to a second direction, and two sidewalls of the channel region along the length direction are recessed inward relative to sidewalls of a corresponding one of the first dielectric portions to form a notch. The source region and the drain region are respectively disposed at two sides of the channel region along the length direction and cover an inner wall of the notch; the gate dielectric layer is located between the gate and the channel region, between the gate and the source region, and between the gate and the drain region. The capacitor is electrically connected to the source region or the drain region of the transistor.

With the aforementioned technical solution, the 3D DRAM provided in the present disclosure not only includes multiple memory groups spaced apart along the second direction within the same layer, but also includes multiple memory layers spaced apart along the first direction. In this case, the memory cells are arranged in a three-dimensional array. Compared to a two-dimensional dynamic random access memory (2D DRAM) having only a single memory layer, each memory layer in the present disclosure can form a structure analogous to the conventional 2D DRAM, while the multiple memory layers stacked along the first direction in the present disclosure can increase the storage density of the provided 3D DRAM multiplicatively, effectively solving the problem of low density in the 2D DRAM.

Furthermore, in each memory cell of the 3D DRAM provided by the present disclosure, the two sidewalls of the channel region in the transistor along the length direction are recessed inward relative to the sidewalls of the corresponding first dielectric portion, forming notches. The source region and the drain region are respectively disposed at the two sides along the length direction and cover the inner walls of the notches. In other words, the source region and the drain region of the transistor are not only disposed on the inner walls of the notches along the length direction of the channel region but also cover the inner walls of the notches along the first direction. With this configuration, compared to the prior art where the source region and drain region of the transistor only extend relative to the length direction of the channel region, the source region and drain region of the transistor provided in the present disclosure additionally have portions covering the inner walls of the notches along the first direction, that is, larger geometric dimensions are achieved in the second direction, resulting in larger areas for the source and drain regions. This thereby increases the contact area between the source region/drain region and a contact structure or capacitor, helps to reduce contact resistance between the source region/drain region and the contact structure or capacitor, improves the speed of the transistor, enhances the storage performance of each memory cell, and mitigates leakage current.

In a possible implementation, a ratio of a height of the notch to a width of the notch is greater than or equal to 0.1 and less than or equal to 10. The height of the notch is parallel to the first direction, and the width of the notch is parallel to the second direction.

With the aforementioned technical solution, when the ratio of the height of the notch to the width of the notch is within the above range, the notch has a relatively large surface area. Since the source region and the drain region cover the inner walls of the notches, compared to the prior art, the source region and drain region in the present disclosure have additional surface area in the height direction of the notch, that is, the first direction, thereby increasing the contact area between the source region/drain region and the contact structure or capacitor. This helps to reduce the contact resistance between the source region/drain region and the contact structure or capacitor, improves the speed of the transistor, and mitigates leakage current. Moreover, it can also prevent notch dimensions from being excessively large, ensuring that during the manufacture of the 3D DRAM provided in the present disclosure, a lateral etch width (namely, the width of the notch) of a first dielectric layer and a gate layer on the first dielectric layer when forming the notches does not become overly large. This reduces the difficulty of lateral etching, thereby improving the manufacturing yield of the 3D DRAM provided herein.

In a possible implementation, a ratio of a length of the channel region to a thickness of the channel region is greater than or equal to 10 and less than or equal to 1000. A thickness direction of the channel region is parallel to the first direction.

In the prior art, the source region and drain region extend from the sidewalls of the channel region only along the second direction. When the ratio of the length to the thickness of the channel region is within the above range, if the source region and drain region only extend along the second direction, the dimensions of the source region and drain region would be small. If the dimensions of the source region and drain region are increased simply by increasing extension lengths of the source region and drain region along the second direction, it is prone to cause collapse of the source region and drain region. With the aforementioned technical solution, in the present disclosure, the source region and drain region not only cover the inner walls of the notches along the second direction but also cover the inner walls of the notches along the first direction. This not only increases the areas of the source region and drain region but also prevents the risk of their collapse, thereby further improving the yield of the 3D DRAM.

In a possible implementation, a ratio of the thickness of the channel region to a width of the notch is greater than or equal to 0.1 and less than or equal to 10. The width of the notch is parallel to the second direction.

With the aforementioned technical solution, the transistor provided in the present disclosure still possesses a source region area and a drain region area located at the two ends along the length direction of the channel region as in the prior art. As described above, the transistor provided in the present disclosure additionally includes a source region area and a drain region area along the first direction. Thus, the source region area and drain region area of the transistor provided in the present disclosure are larger than those in the prior art. The beneficial effects are as described previously and will not be reiterated here.

In a possible implementation, a material of the channel region includes indium gallium zinc oxide.

With the aforementioned technical solution, indium gallium zinc oxide has a relatively high carrier mobility, which can enable the transistor provided in the present disclosure to have faster signal transmission and switching speeds, thereby improving the operating efficiency and response speed of the 3D DRAM provided in the present disclosure. Furthermore, a transistor whose channel region material includes indium gallium zinc oxide has a small current in an off-state, which helps to reduce the power consumption of the 3D DRAM provided in the present disclosure and extends the battery life of electronic devices incorporating the 3D DRAM provided in the present disclosure. It can also reduce the requirements for a thermal management system, thereby enhancing the reliability and stability of electronic devices incorporating the 3D DRAM provided in the present disclosure. Meanwhile, during the manufacture of the 3D DRAM provided in the present disclosure, the channel region made of indium gallium zinc oxide can be formed using low-temperature processes. Low-temperature processes can reduce the need for expensive high-temperature equipment and complex process steps, potentially lowering costs, and also reduce the risk of thermal damage to the three-dimensional memory, thereby improving chip yield. Additionally, although the structural strength of the channel region is relatively low when the channel region is made of indium gallium zinc oxide, the channel region manufactured in the present disclosure is not suspended during the manufacturing process and will not collapse due to its low structural strength.

In a possible implementation, the source region, the drain region, and the channel region are integrally continuous.

With the aforementioned technical solution, during the manufacture of the 3D DRAM provided in the present disclosure, the source region, the drain region, and the channel region can be formed in the same process step. This can reduce the number of process steps, lower manufacturing costs, and improve production yield.

In a possible implementation, the gate includes a first gate and a second gate respectively disposed at two sides of the channel region along the first direction.

With the aforementioned technical solution, the transistor provided in the present disclosure is a double-gate transistor. Conventional transistors have only one gate to control the current in the channel region, whereas the transistor provided in the present disclosure has two gates. The double-gate transistor can have twice the gate control area for the same channel region area, effectively enhancing the control capability of the gates over the channel region. This enables finer and more flexible control over carriers in the channel region by the gates, allowing more effective regulation of current turn-on and turn-off, thereby improving the switching performance of the transistor provided in the present disclosure. It can effectively suppress short-channel effects, which is beneficial for further reducing the size of the transistor provided in the present disclosure, thus increasing the storage density of the 3D DRAM provided in the present disclosure. For example, under low-voltage operation, the double-gate transistor can control the current more precisely, achieving faster switching transitions, which helps to reduce the power consumption of the 3D DRAM provided in the present disclosure.

In a possible implementation, the 3D DRAM further includes contact structures. Of the source region and the drain region of the transistor, when the source region is electrically connected to the capacitor, the drain region is electrically connected to a corresponding one of the contact structures; or, of the source region and the drain region of the transistor, when the drain region is electrically connected to the capacitor, the source region is electrically connected to a corresponding one of the contact structures. The dielectric structure further includes second dielectric portions and third dielectric portions. The second dielectric portions are respectively located between two adjacent ones of the capacitors spaced apart along the third direction and between two adjacent ones of the contact structures spaced apart along the third direction. The third dielectric portions are respectively located between two adjacent ones of the transistors spaced apart along the third direction.

With the aforementioned technical solution, the second dielectric portions and the third dielectric portions electrically isolate the plurality of memory cells spaced apart along the second direction, enabling separate access to the plurality of memory cells spaced apart along the second direction.

In a possible implementation, the capacitors each include a first electrode, a dielectric layer, and a second electrode. The dielectric layer is located between the first electrode and the second electrode. Each of the first electrodes fills a corresponding one of the notches. The dielectric layer and the second electrode are disposed between two adjacent ones of the transistors spaced apart along the second direction. The dielectric layers in the different capacitors spaced apart along the first direction are integrally continuous, and the second electrodes in the different capacitors spaced apart along the first direction are integrally continuous.

With the aforementioned technical solution, the first electrode can also be used as the source electrode or drain electrode of the transistor provided in the present disclosure and as one plate of the capacitor of the memory cell of the present disclosure, thereby connecting the transistor and the capacitor to form a one-transistor-one-capacitor (1T1C) memory cell of a DRAM. Furthermore, the integrally continuous second electrode and dielectric layer allow the dielectric layers of different capacitors to be formed simultaneously and the second electrodes of different capacitors to be formed simultaneously during the manufacture of the 3D DRAM provided in the present disclosure. This reduces the process steps required for separately forming the dielectric layers and second electrodes of different capacitors, which is beneficial for reducing cost and improving production yield.

According to a second aspect, the present disclosure further provides a manufacturing method of a 3D DRAM, including: forming a plurality of memory cells arranged in a three-dimensional array, where the plurality of memory cells arranged in the three-dimensional array include a plurality of memory layers spaced apart along a first direction, each of the memory layers includes a plurality of memory groups spaced apart along a second direction, and each of the memory groups includes a plurality of the memory cells distributed along a third direction; the first direction, the second direction, and the third direction are different from each other; each of the memory cells includes a transistor and a capacitor; and forming a dielectric structure configured to isolate the plurality of the memory cells, where the dielectric structure includes first dielectric portions respectively located between adjacent ones of the transistors spaced apart along the first direction; the transistors each comprise: a gate, a gate dielectric layer, a channel region, a source region, and a drain region; a length direction of the channel region is parallel to the second direction, and two sidewalls of the channel region along the length direction are recessed inward relative to sidewalls of a corresponding first dielectric portion to form a notch; the source region and the drain region are respectively disposed at two sides of the channel region along the length direction and cover an inner wall of the notch; the gate dielectric layer is located between the gate and the channel region, between the gate and the source region, and between the gate and the drain region.

Compared with the prior art, the beneficial effects of the manufacturing method of a 3D DRAM provided in the present disclosure are the same as those of the 3D DRAM according to the aforementioned technical solution, and thus will not be repeated here.

In a possible implementation, the forming the plurality of memory cells arranged in the three-dimensional array and forming the dielectric structure configured to isolate the plurality of the memory cells from each other are implemented as follows: a stack structure and second dielectric portions penetrating the stack structure are formed, where the stack structure includes a plurality of stack units stacked along the first direction; each of the stack units includes a first dielectric layer and a laminate located on the first dielectric layer; the laminate includes a second dielectric layer and the gate that are stacked; a material of the first dielectric layer is different from a material of the second dielectric layer; the stack structure is provided with first via groups and second via groups spaced apart along the second direction; the first via groups and the second via groups each include a plurality of vias spaced apart along the third direction; the second dielectric portions are respectively disposed between two adjacent vias along the first direction within a same one of the first via groups and disposed between two adjacent vias along the first direction within a same one of the second via groups; the first dielectric portion includes the first dielectric layer. Next, an edge portion of each of the gates is selectively removed to form the notches. Then, the second dielectric layers are selectively etched such that remaining portions of the second dielectric layers form third dielectric portions, where the third dielectric portions are respectively located between two adjacent ones of the transistors spaced apart along the third direction; the dielectric structure includes the first dielectric portions, the second dielectric portions, and the third dielectric portions. Next, deposition is performed to form the gate dielectric layers each covering a periphery of a corresponding one of the gates; and deposition is performed to form the channel region, the source region, and the drain region on each of the gate dielectric layers. Then, a contact structure is formed in each of the vias of the first via groups, and a first electrode of the capacitor is formed in a notch-aligned portion of each of the vias of the second via groups. Further, a dielectric layer and a second electrode are sequentially formed in each of the vias of the second via groups, where the capacitor includes the first electrode, the dielectric layer, and the second electrode.

With the aforementioned technical solution, the first dielectric portion includes all of the first dielectric layers, and all of the removed second dielectric portions serve as pre-placeholder structures for the channel regions. After removal, the gate dielectric layer covering the periphery of the gate is deposited, followed by deposition of the channel region, source region, and drain region on the gate dielectric layer. In the prior art, during the manufacture of transistors, sacrificial layers at both sides of a channel region are first removed, and then a gate dielectric layer and a gate are formed at two sides of the channel region along the first direction and second direction. At this point, the channel region is suspended. Since the channel region is made of a semiconductor material with relatively low structural strength, and given that the memory cells have small geometric dimensions, the channel region made of the semiconductor material with a high aspect ratio along the second direction is prone to collapse, leading to transistor deformation. This causes performance degradation or even failure of the memory cells, which reduces yield. Based on this, in the manufacturing of the 3D DRAM in the present disclosure, after the second dielectric layer is selectively etched such that the remaining second dielectric layer forms the third dielectric portion, the gate is suspended. Compared to the channel region material, the gate material has higher structural strength and is less likely to collapse, even with a high aspect ratio along the second direction when the memory cells have small geometric dimensions. The manufacturing method of a 3D DRAM provided in the present disclosure can ensure the structural integrity of the transistors, thereby ensuring the proper operation and performance stability of the memory cells manufactured by the manufacturing method of a 3D DRAM provided in the present disclosure, and thus improving yield.

In a possible implementation, the forming the stack structure and the second dielectric portions penetrating the stack structure is implemented as follows: a stack material layer is formed. Next, third via groups and fourth via groups penetrating the stack material layer are formed, where an aperture pattern of the third via group is the same as a top pattern of the second dielectric layer. Then, the second dielectric portions filling the third via groups and the fourth via groups are formed.

With the aforementioned technical solution, compared with the prior art, the beneficial effects of the manufacturing method of a 3D DRAM provided in the present disclosure are the same as those of the 3D DRAM in the aforementioned technical solution, and thus will not be repeated here.

In a possible implementation, a diameter of each via in the first via groups is greater than or equal to 30 nm and less than or equal to 3000 nm.

With the aforementioned technical solution, it is possible to avoid overly stringent requirements on etching and photolithography processes caused by an excessively small via diameter, which would lead to high costs, thus helping to reduce costs. It can also prevent difficulties in uniformly forming the contact structure on the hole wall or even forming the contact structure at all due to an excessively small via diameter. Furthermore, it can avoid the situation where an excessively large via diameter occupies too much area, which would reduce the storage density of the 3D DRAM manufactured according to the present disclosure.

In a possible implementation, a diameter of each via in the second via groups is greater than or equal to 50 nm and less than or equal to 5000 nm.

With the aforementioned technical solution, it is possible to avoid overly stringent requirements on etching and photolithography processes caused by an excessively small via diameter, which would lead to high costs, thus helping to reduce costs. It can also prevent the situation where an excessively small via diameter results in a smaller capacitor area, which would reduce the retention time of the capacitor and lead to a higher refresh frequency, thereby increasing power consumption. Thus, it helps to reduce the power consumption of the 3D DRAM manufactured according to the present disclosure. Furthermore, it can avoid the situation where an excessively large via diameter occupies too much area, which would reduce the storage density of the 3D DRAM manufactured according to the present disclosure. Additionally, during forming of the first electrodes and the contact structures, a material layer for the first electrodes and contact structures is formed by deposition on the surface of the manufactured 3D DRAM of the present disclosure. The material layer is subsequently etched to form the first electrodes and the contact structures. Because the via diameter of each via in the first via groups is smaller than that in the second via groups, the material layer fills each via of the first via groups but only forms on the inner walls of each via in the second via groups. During subsequent etching, only the material layer at the top of each via in the first via groups and the material layer on the inner walls of each via in the second via groups are removed. This process allows the first electrodes and contact structures to be formed without the need for a mask, reducing the number of process steps, lowering costs, and improving production yield.

### BRIEF DESCRIPTION OF THE DRAWINGS

The accompanying drawings described herein are provided for further understanding of this application, and constitute a part of this application. The exemplary embodiments of this application and illustrations thereof are intended to explain this application, but do not constitute inappropriate limitations to this application. In the accompanying drawings:

FIG. 1 is a schematic diagram of a 3D DRAM provided by an embodiment of the present disclosure;

FIG. 2 is a schematic diagram of forming a stack material layer in an embodiment of the present disclosure;

FIG. 3 is a schematic diagram of forming third via groups and fourth via groups in an embodiment of the present disclosure;

FIG. 4 is a schematic diagram of forming second dielectric portions in an embodiment of the present disclosure;

FIG. 5 is a schematic diagram of forming first via groups and second via groups in an embodiment of the present disclosure;

FIG. 6 is a schematic diagram of forming notches in an embodiment of the present disclosure;

FIG. 7 is a schematic diagram of removing second dielectric layers in an embodiment of the present disclosure;

FIG. 8 is a schematic diagram of forming gate dielectric layers in an embodiment of the present disclosure;

FIG. 9 is a cross-sectional view of forming channel layers taken along a first direction and a second direction in an embodiment of the present disclosure;

FIG. 10 is a cross-sectional view of forming electrode layers taken along a first direction and a second direction in an embodiment of the present disclosure;

FIG. 11 is a cross-sectional view of forming first electrodes and contact structures taken along a first direction and a second direction in an embodiment of the present disclosure; and

FIG. 12 is a schematic diagram of forming dielectric layers and forming second electrodes in an embodiment of the present disclosure.

### REFERENCE NUMERALS

100—memory cell, 101—channel region, 102—source region, 103—drain region, 104—notch, 105—channel layer, 110—gate, 111—first gate, 112—second gate, 120—gate dielectric layer, 130—contact structure, 140—transistor;
200—capacitor, 201—first electrode, 202—dielectric layer, 203—second electrode, 204—electrode layer;
310—first dielectric portion, 311—first dielectric layer, 320—second dielectric portion, 331—second dielectric layer, 332—third dielectric portion;
410—first via group, 420—second via group, 430—third via group, 440—fourth via group.

### DETAILED DESCRIPTION OF THE EMBODIMENTS

To make the to-be-resolved technical problems, technical solutions and beneficial effects of the embodiments of the present disclosure clearer, the embodiments of the present disclosure are described in further detail below with reference to the drawings and embodiments. It should be understood that the specific embodiments described herein are merely intended to explain the embodiments of the present disclosure, rather than to limit the embodiments of the present disclosure.

It should be noted that when a component is “fixed” or “provided” on another component, the component may be “fixed” or “provided” on the another component directly or indirectly. When a component is “connected” to another component, the component may be “connected” to the another component directly or indirectly.

In addition, the terms “first” and “second” are merely intended for a purpose of description, and shall not be understood as an indication or implication of relative importance or implicit indication of a quantity of indicated technical features. Thus, features defined with “first” and “second” may explicitly or implicitly include one or more of the features. In the description of the embodiments of the present disclosure, “a plurality of” means two or more, unless otherwise specifically defined. In the description of the present disclosure, “several” means one or more, unless otherwise specifically defined.

In the description of the embodiments of the present disclosure, it needs to be understood the orientation or positional relationships indicated by terms, such as “up”, “down”, “front”, “rear”, “left”, and “right”, are based on the orientation or positional relationship shown in the accompanying drawings, are merely for facilitating the description of the embodiments of the present disclosure and simplifying the description, rather than indicating or implying that an apparatus or element referred to must have a particular orientation or be constructed and operated in a particular orientation, and therefore shall not be interpreted as limiting the embodiments of the present disclosure.

In the description of the embodiments of the present disclosure, it should be noted that unless otherwise expressly specified, terms such as “mounted”, “connected to”, and “connected with” should be comprehended in a broad sense. For example, the “connection” may be a fixed connection, a removable connection, or an integral connection; may be a mechanical connection or an electrical connection; may be a direct connection or an indirect connection via an intermediate medium; or may be an interconnection or an interaction relationship between two elements. Those of ordinary skill in the art may understand specific meanings of the foregoing terms in the embodiments of the present disclosure based on a specific situation.

In computer systems, memory is a critical component for storing data and programs. DRAM, as an important type of memory, plays a key role in modern computer architectures. Common DRAM typically includes a 1T1C memory cell structure. Each memory cell of such DRAM includes one transistor and one capacitor connected to the source or drain of the transistor. The capacitor is used to store charge, and the transistor is used to control access to the capacitor. Such DRAM also includes a word line connected to the gate of the transistor and a bit line connected to one of the source region and the drain region of the transistor that is not connected to the capacitor. During access to data in a particular memory cell, the word line connected to the memory cell is selected, and a voltage that turns on the transistor is applied to the word line, to turn on the transistor. Then, the bit line connected to that memory cell is selected, thereby completing the selection of the memory cell and allowing access to the charge in the capacitor. However, since the capacitor gradually leaks electricity, leading to a decrease in stored charge, DRAM requires regular refresh (typically every few milliseconds) to maintain data validity. The refresh operation reads data in each memory cell and rewrites the data, thereby replenishing the charge lost from each capacitor.

In the prior art, memory cells of DRAM are arranged in an array along the horizontal direction of the wafer, which is known as 2D DRAM. In the 2D DRAM, transistors are arranged in an array on the wafer. Capacitors can either be distributed in the same plane as the transistors in the same manner, or disposed above or below the transistors to improve storage density. However, the development of computer systems has imposed higher requirements on the density of DRAM. The density of the aforementioned two types of 2D DRAM is limited by manufacturing processes, and neither transistors nor capacitors can be scaled down indefinitely to meet the density requirements.

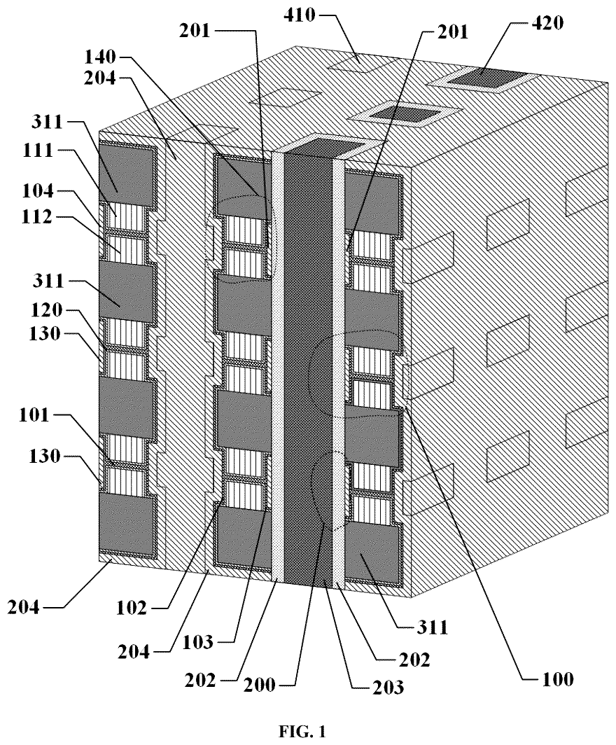

To resolve the foregoing problem, according to a first aspect, an embodiment of the present disclosure provides a 3D DRAM. Referring to FIG. 1, a 3D DRAM includes: a plurality of memory cells 100 arranged in a three-dimensional array, and a dielectric structure configured to isolate the plurality of the memory cells 100. The plurality of memory cells 100 arranged in the three-dimensional array include a plurality of memory layers spaced apart along a first direction, each of the memory layers includes a plurality of memory groups spaced apart along a second direction, and each of the memory groups includes a plurality of the memory cells 100 distributed along a third direction. The first direction, the second direction, and the third direction are different from each other. Each of the memory cells 100 includes: a transistor 140 and a capacitor 200; the dielectric structure includes first dielectric portions 310 respectively located between adjacent ones of the transistors 140 spaced apart along the first direction. The transistor 140 includes: a gate 110, a gate dielectric layer 120, a channel region 101, a source region 102, and a drain region 103. A length direction of the channel region 101 is parallel to the second direction, and two sidewalls of the channel region 101 along the length direction are recessed inward relative to sidewalls of a corresponding first dielectric portion 310 to form a notch 104. The source region 102 and the drain region 103 are respectively disposed at two sides along the length direction and cover an inner wall of the notch 104. The gate dielectric layer 120 is located between the gate 110 and the channel region 101, between the gate 110 and the source region 102, and between the gate 110 and the drain region 103. The capacitor 200 is electrically connected to the source region 102 or the drain region 103 of the transistor 140.

With the aforementioned technical solution, as shown in FIG. 1, a plurality of memory cells 100 distributed along the third direction form a memory group, a plurality of memory groups spaced apart along the second direction form a memory layer, and a plurality of memory layers spaced apart along the first direction form the plurality of memory cells 100 arranged in a three-dimensional array, constituting the 3D DRAM provided in the embodiment of the present disclosure. Compared with the prior art, the memory layers in the embodiment of the present disclosure form a structure analogous to the conventional 2D DRAM, while the plurality of memory layers are stacked along the first direction, increasing the storage density of the 3D DRAM provided in the embodiment of the present disclosure multiplicatively, thus effectively solving the problem of low density in the 2D DRAM.

Furthermore, as shown in FIG. 1, in the memory cells 100 of the 3D DRAM provided by the embodiment of the present disclosure, the two sidewalls of the channel region 101 of the transistor 140 along the length direction are recessed inward relative to the sidewalls of the corresponding first dielectric portion 310, forming the notches 104. The source region 102 and the drain region 103 are respectively disposed at the two sides along the length direction and cover the inner walls of the notches 104. In other words, the source region 102 and the drain region 103 of the transistor 140 are not only disposed on the inner walls of the notches 104 along the length direction of the channel region 101 but also cover the inner walls of the notches 104 along the first direction. With this configuration, compared to the prior art where the source region 102 and drain region 103 of the transistor 140 only extend relative to the length direction of the channel region 101, the source region 102 and drain region 103 of the transistor 140 provided in the embodiment of the present disclosure additionally have portions covering the inner walls of the notches 104 along the first direction, that is, larger geometric dimensions are achieved in the second direction, resulting in larger areas for the source region 102 and drain region 103. This thereby increases the contact area between the source region 102/drain region 103 and a contact structure 130 or capacitor 200, helps to reduce contact resistance between the source region 102/drain region 103 and the contact structure 130 or capacitor 200, improves the speed of the transistor 140, and mitigates leakage current.

In practical applications, the specific arrangement directions and distribution of different memory cells 100 are not specifically limited in the embodiment of the present disclosure, as long as the different memory cells 100 are arranged in a three-dimensional array. As for the specific directions represented by the aforementioned first direction, second direction, and third direction, there are no specific limitations, as long as any two of the three directions are different.

For example, the first direction is the height direction of the 3D DRAM provided by the embodiment of the present disclosure. Furthermore, the second direction and the third direction can be determined based on the distribution of different memory cells 100 within the same memory layer.

For example, referring to FIG. 1, when different memory cells 100 in the same memory layer are distributed in a rectangular array, the second direction and the third direction can be the directions of the length and width of the rectangular array, respectively.

In another example, when different memory cells 100 in the same memory layer are distributed in a parallelogram array, the second direction and the third direction can be the directions of two adjacent sides of the parallelogram array, respectively.

In further another example, when different memory cells 100 in the same memory layer are distributed in a concentric circular array, the second direction and the third direction can be the radial direction and the circumferential direction of the concentric circular array, respectively.

It can be understood that when the distribution of memory cells in the same memory layer varies, the second direction and the third direction can be changed accordingly.

In practical applications, the specific shape and distribution of the dielectric structure are not specifically limited in the embodiment of the present disclosure, as long as different memory cells 100 can be isolated.

Specifically, referring to FIG. 1, the dielectric structure includes first dielectric portions 310 respectively located between adjacent ones of the transistors 140 spaced apart along the first direction. The first dielectric portion 310 protrudes beyond the channel region 101 in the second direction to form a notch 104.

In practical applications, the material of the first dielectric portion 310 is not specifically limited in the embodiment of the present disclosure, as long as the first dielectric portion 310 can insulate and isolate the gates 110 of two adjacent transistors 140 along the first direction. For example, the first dielectric portion 310 can be made of silicon oxide or silicon nitride. The first dielectric layer 311 can also be a combination of multiple materials, as long as it is feasible in the manufacturing process.

It can be understood that a distance between two adjacent layers of the first dielectric portion 310 along the first direction is determined by the dimension along the first direction of the transistor located between the two adjacent layers of the first dielectric portion 310. Exemplarily, the distance between two adjacent layers of the first dielectric portion 310 can be 5 nm to 500 nm.

The thickness of the first dielectric portion 310 is not specifically limited in the embodiment of the present disclosure, as long as the first dielectric portion 310 can insulate and isolate the gates 110 of two adjacent transistors 140 along the first direction. For example, the thickness of the first dielectric portion 310 of each layer can be 10 nm to 1000 nm.

Regarding the shape of the notch 104, specifically, referring to FIG. 1, the bottom of the notch 104 is formed by the sidewalls of the gate 110 and the channel region 101 along the first direction; the sidewalls of the notch 104 are formed, in the first direction, by opposing surfaces of the protruding portions of the first dielectric portion 310 located at both sides of the transistor 140, and in the third direction, by a structure for isolating two adjacent memory cells 100 along the third direction.

It can be understood that the 3D DRAM provided in the embodiment of the present disclosure further includes a plurality of contact structures 130 that can serve as data lines or bit lines, and second dielectric portions 320 for isolating the contact structures 130 distributed along the third direction. Each contact structure 130 is connected, along the first direction, to the source regions 102 or the drain regions 103 of the transistors 140 of a plurality of memory cells 100, and along the second direction, connects the source regions 102 or the drain regions 103 of the transistors 140 of two adjacent memory cells 100. The second dielectric portion 320 penetrates through the 3D DRAM provided in the embodiment of the present disclosure to achieve complete isolation of two adjacent contact structures 130 along the third direction.

In practical applications, the material of the contact structure 130 is not specifically limited in the embodiment of the present disclosure and can be determined based on the performance and manufacturing process requirements of the 3D DRAM provided in the embodiment of the present disclosure. Exemplarily, the material of the contact structure 130 can be at least one of copper, aluminum, chromium, or tungsten.

In practical applications, the material of the second dielectric portion 320 is not specifically limited in the embodiment of the present disclosure, as long as the second dielectric portion 320 meets the requirement of insulating, in the third direction, structures within two adjacent vias in a first via group 410 that are located at two sides of the second dielectric portion 320, and insulating, in the third direction, structures within two adjacent vias in a second via group 420 that are located at two sides of the second dielectric portion 320.

It should be noted that the material of the first dielectric portion 310 and the material of the second dielectric portion 320 can be the same or different, which can be determined by the manufacturing process.

It can be understood that, referring to FIG. 1, along the third direction, the dielectric structure includes third dielectric portions 332. The third dielectric portions 332 are respectively located between two adjacent transistors 140 spaced apart along the third direction. The third dielectric portion 332 at least electrically isolates the channel regions 101 of two adjacent transistors 140 spaced apart along the third direction, to facilitate individual access to two adjacent memory cells 100 including the two adjacent transistors 140 distributed along the third direction. The gates 110 of the two adjacent transistors 140 spaced apart along the third direction are connected to each other, forming a word line of the 3D DRAM provided in the embodiment of the present disclosure. Furthermore, along the third direction, the region of the gate 110 between two adjacent transistors 140 is not recessed from the first dielectric portion 310, and together with the sidewall of the third dielectric portion 332, forms the sidewall of the notch 104 along the third direction. The gate dielectric layer 120 is also disposed on the sidewall of the notch 104 along the third direction, thereby further increasing the contact area between the source region 102/drain region 103 and the capacitor 200 or the contact structure 130.

The material of the third dielectric portion 332 is different from both the material of the first dielectric portion 310 and the material of the second dielectric portion 320. With reference to the subsequent content, this is conducive to the selective etching of the third dielectric portion 332. For example, when the materials of the first dielectric portion 310 and the second dielectric portion 320 are the same and both are silicon oxide, the third dielectric portion 332 can be silicon nitride.

Referring to FIG. 1, each memory cell 100 of the 3D DRAM provided by the embodiment of the present disclosure includes one transistor 140 and one capacitor 200, forming a 1T1C DRAM structure.

In practical applications, the connection relationship between the transistor 140 and the capacitor 200 of the memory cell 100 is not specifically limited in the embodiment of the present disclosure and can be determined based on the conductivity type of the transistor 140 and actual requirements. Exemplarily, of the source region 102 and the drain region 103 of the transistor 140, when the source region 102 is electrically connected to the capacitor 200, the drain region 103 is electrically connected to the contact structure 130. Alternatively, as shown in FIG. 1, of the source region 102 and the drain region 103 of the transistor 140, when the drain region 103 is electrically connected to the capacitor 200, the source region 102 is electrically connected to the contact structure 130.

It should be noted that the accompanying drawings provided in the embodiment of the present disclosure only illustrate the case where the drain region 103 is electrically connected to the capacitor 200 and the source region 102 is electrically connected to the contact structure 130, but this does not mean that only the above connection relationship is possible. For the specific connection relationship between the source region 102/drain region 103 in the transistor 140 and the contact structure 130 or the capacitor 200, reference can be made to the foregoing description: when the drain region 103 is electrically connected to the capacitor 200, the source region 102 is electrically connected to the contact structure 130.

It can be understood that, along the third direction, the second dielectric portions 320 also isolate the capacitors 200 included multiple memory cells 100 to achieve isolation of data stored in the multiple memory cells 100.

Referring to FIG. 1, the transistor 140 includes: a gate 110, a gate dielectric layer 120, a channel region 101, a source region 102, and a drain region 103.

Structurally, the length direction of the channel region 101 is parallel to the second direction, and two sidewalls of the channel region 101 along the length direction are recessed inward relative to sidewalls of a corresponding first dielectric portion 310 to form a notch 104; the source region 102 and the drain region 103 are respectively disposed at two sides along the length direction and cover an inner wall of the notch 104; the gate dielectric layer 120 is located between the gate 110 and the channel region 101, between the gate 110 and the source region 102, and between the gate 110 and the drain region 103. Since the channel region 101, the source region 102, and the drain region 103 are formed subsequently relative to the gate 110, they are not suspended during the manufacture of the 3D DRAM provided by the embodiment of the present disclosure, which helps to prevent collapse due to the low structural strength of the channel region 101, the source region 102, and the drain region 103, thereby ensuring the structural integrity of the transistor 140. This thereby ensures the normal operation and performance stability of the memory cells 100 manufactured by the manufacturing method of a 3D DRAM provided in the present disclosure, thus improving yield.

In practical applications, the structure of the gate 110 of the transistor 140 is not specifically limited in the embodiment of the present disclosure and can be determined based on performance requirements for the 3D DRAM of the embodiment of the present disclosure. Regarding the structure of the gate 110, the transistor 140 can be a conventional single-gate transistor or a double-gate transistor, or other possible structures for the gate 110 can be adopted.

Exemplarily, the transistor 140 is a conventional single-gate transistor. Along the first direction, the gate 110 is disposed on the first dielectric portion 310; the gate dielectric layer 120 is disposed on the gate 110; the channel region 101, the source region 102, and the drain region 103 are simultaneously disposed on the gate 110 and the first dielectric portion 310.

Exemplarily, the transistor 140 is a double-gate transistor. Referring to FIG. 1, along the first direction, the first gate 111 and the second gate 112 of the gate 110 are respectively disposed on two adjacent layers of the first dielectric portion 310, and edges of the first gate 111 and the second gate 112 are recessed between the adjacent layers of the first dielectric portion 310 along the second direction, forming the notches 104. That is, projections of the first gate 111 and the second gate 112 in the second direction are smaller than projections of the first dielectric portion 310 in the second direction. Between the two adjacent layers of the first dielectric portion 310, the gate dielectric layer 120 covering the periphery of the gate 110 is disposed on the first gate 111, the second gate 112, and the inner walls of the notches 104; the channel region 101, the source region 102, and the drain region 103 covering the periphery of the gate dielectric layer 120 are disposed on the gate dielectric layer 120. The gate 110, the gate dielectric layer 120, the channel region 101, the source region 102, and the drain region 103 form the transistor 140. The transistor 140 provided in the embodiment of the present disclosure has two gates. The double-gate transistor can have a larger gate control area for the same area of the channel region 101, effectively enhancing the control capability of the gate 110 over the channel region 101. This enables finer and more flexible control of carriers in the channel region 101 by the gate 110, allowing more effective regulation of current turn-on and turn-off, thereby improving the switching performance of the transistor 140 provided in the embodiment of the present disclosure. For example, under low-voltage operation, the double-gate transistor can control the current more precisely, achieving faster switching transitions, which helps to reduce the power consumption of the 3D DRAM provided in the embodiment of the present disclosure. Moreover, the transistor 140 provided in the embodiment of the present disclosure being a double-gate transistor can effectively suppress short-channel effects, which is beneficial for further reducing the size of the transistor 140 provided in the embodiment of the present disclosure, thus increasing the storage density of the 3D DRAM provided in the embodiment of the present disclosure.

The source region 102, the drain region 103, and the channel region 101 can be manufactured simultaneously and be integrally continuous; alternatively, the source region 102, the drain region 103, and the channel region 101 can also be formed separately, where the source region 102 and the channel region 101 are connected at the bottom of one notch 104 of the transistor 140, and the drain region 103 and the channel region 101 are connected at the bottom of the other notch 104.

Optionally, the source region 102, the drain region 103, and the channel region 101 are integrally continuous. In this case, during the manufacture of the 3D DRAM provided by the embodiment of the present disclosure, the source region 102, the drain region 103, and the channel region 101 can be formed in the same process step, which can reduce the number of process steps, lower manufacturing costs, and improve production yield.

In practical applications, the material of the channel region 101 is not specifically limited in the embodiment of the present disclosure, as long as the material properties can meet the speed requirements of the 3D DRAM provided by the embodiment of the present disclosure. The material of the channel region 101 can be conventional silicon material, or materials with high electron mobility such as germanium, silicon-germanium, or indium gallium zinc oxide to reduce the resistivity of the channel region 101 and improve the speed of the transistor 140.

Optionally, the material of the channel region 101 includes indium gallium zinc oxide. In this case, indium gallium zinc oxide has a relatively high carrier mobility, meaning that electrons move faster within the material, which can enable the transistor 140 provided in the embodiment of the present disclosure to have faster signal transmission and switching speeds, thereby improving the operating efficiency and response speed of the 3D DRAM provided in the embodiment of the present disclosure. Moreover, the transistor 140 with the channel region 101 made of indium gallium zinc oxide has a very small current in the off-state, which helps to reduce the power consumption of the 3D DRAM provided in the embodiment of the present disclosure and extends the battery life of electronic devices incorporating the 3D DRAM provided in the embodiment of the present disclosure. It can also reduce the requirements for a thermal management system, thereby enhancing the reliability and stability of electronic devices incorporating the 3D DRAM provided in the embodiment of the present disclosure. Meanwhile, during the manufacture of the 3D DRAM provided in the embodiment of the present disclosure, the channel region 101 made of indium gallium zinc oxide can be formed using low-temperature processes. Low-temperature processes can reduce the need for expensive high-temperature equipment and complex process steps, potentially lowering costs, and also reduce the risk of thermal damage to the three-dimensional memory, thereby improving chip yield.

In practical applications, the material of the source region 102 and the drain region 103 can be different from the material of the channel region 101, or can be the same as the material of the channel region 101. This is not specifically limited in the embodiment of the present disclosure, as long as it meets the design and process requirements of the 3D DRAM provided in the embodiment of the present disclosure. When the material of the source region 102 and the drain region 103 is the same as the material of the channel region 101, it is conducive to forming integrally continuous source region 102, drain region 103, and channel region 101; alternatively, the source region 102, drain region 103, and channel region 101 can be formed separately. When the material of the source region 102 and the drain region 103 is different from the material of the channel region 101, it is conducive to forming the source region 102, drain region 103, and channel region 101 separately.

In practical applications, the material of the gate dielectric layer 120 is not specifically limited in the embodiment of the present disclosure, as long as it can be applied to the 3D DRAM provided in the embodiment of the present disclosure. For example, a high-k dielectric material including hafnium dioxide can be used, which facilitates reducing the thickness of the gate dielectric layer 120, thereby reducing the suspended height during the manufacture of the transistor 140 provided in the embodiment of the present disclosure, effectively avoiding structural damage caused by suspension, and thus improving yield; it can also reduce the thickness of the transistor 140 to increase storage density.

In practical applications, the material of the gate 110 is not specifically limited in the embodiment of the present disclosure, as long as parameters of the material of the gate 110 meet the design and process requirements of the 3D DRAM provided in the embodiment of the present disclosure. For example, the material of the gate 110 can be copper, aluminum, or tungsten. Optionally, the material of the gate 110 is tungsten, because tungsten is stable in nature, less prone to diffusion into other structures, and is less likely to be affected by high-temperature process steps during the manufacture of the 3D DRAM provided in the embodiment of the present disclosure, preventing shape changes and ensuring the performance of the 3D DRAM provided in the embodiment of the present disclosure.

Furthermore, referring to FIG. 1, regarding the notches 104, since the source region 102 and the drain region 103 are disposed on the inner walls of the notches 104, the surface area of the inner wall of the notch 104 is the contact area between the source region 102/drain region 103 and the contact structure or capacitor. Therefore, to reduce the contact resistance between the source region 102/drain region 103 and the contact structure or capacitor, the shape of the notch 104 is defined as follows in the embodiment of the present disclosure:
Specifically, referring to FIG. 1, a ratio of a height of the notch 104 to a width of the notch 104 is greater than or equal to 0.1 and less than or equal to 10. The height of the notch 104 is parallel to the first direction, and the width of the notch 104 is parallel to the second direction. In this case, when the ratio of the height of the notch 104 to the width of the notch 104 is within the above range, the notch 104 has a relatively large surface area. Since the source region 102 and the drain region 103 cover the inner walls of the notches 104, compared to the prior art, the source region 102 and drain region 103 in the present disclosure have additional surface area in the height direction of the notch 104, that is, the first direction, thereby increasing the contact area between the source region 102/drain region 103 and the contact structure 130 or capacitor 200. This helps to reduce the contact resistance between the source region 102/drain region 103 and the contact structure 130 or capacitor 200, improves the speed of the transistor 140, and mitigates leakage current. Moreover, it prevents the dimensions of the notch 104 from being excessively large, ensuring that during the manufacture of the 3D DRAM provided in the embodiment of the present disclosure, a lateral etch width (namely, the width of the notch 104) of the first dielectric portion 310 and a layer of the gates 110 on the first dielectric portion 310 when forming the notches 104 does not become overly large. This reduces the difficulty of lateral etching, thereby improving the manufacturing yield of the 3D DRAM provided herein.

Further, referring to FIG. 1, a ratio of a length of the channel region 101 to a thickness of the channel region 101 is greater than or equal to 10 and less than or equal to 1000. A thickness direction of the channel region 101 is parallel to the first direction. In this case, in the prior art, the source region 102 and the drain region 103 extend from the sidewalls of the channel region 101 along the second direction. When the ratio of the length to the thickness of the channel region 101 is within the above range, if the source region 102 and the drain region 103 only extend along the second direction, the dimensions of the source region 102 and the drain region 103 would be small. If the dimensions of the source region 102 and the drain region 103 are increased simply by increasing extension lengths of the source region 102 and the drain region 103 along the second direction, it is prone to cause collapse of the source region 102 and the drain region 103. Based on this, in the embodiment of the present disclosure, the source region 102 and the drain region 103 not only cover the inner walls of the notches 104 along the second direction but also cover the inner walls of the notches 104 along the first direction. This not only increases the areas of the source region 102 and the drain region 103 but also prevents the risk of collapse of the source region 102 and the drain region 103, thereby further improving the yield of the 3D DRAM.

Furthermore, a ratio of a thickness of the channel region 101 to a width of the notch 104 is greater than or equal to 0.1 and less than or equal to 10. The width of the notch 104 is parallel to the second direction. In this case, the transistor 140 provided in the embodiment of the present disclosure still possesses an area for the source region 102 and an area for the drain region 103 located at the two ends along the length direction of the channel region 101 as in the prior art. As described above, the transistor 140 provided in the embodiment of the present disclosure additionally includes an area for the source region 102 and an area for the drain region 103 along the first direction. Thus, the area of the source region 102 and the area of the drain region 103 of the transistor 140 provided in the embodiment of the present disclosure are larger than the area of the source region 102 and the area of the drain region 103 of the transistor 140 in the prior art. The beneficial effects are as described previously and will not be reiterated here.

Moreover, each transistor 140 includes two notches 104 distributed along the second direction. A source region 102 and a drain region 103 are respectively formed within the two notches 104, as well as other structures connected to the source region 102 or the drain region 103, respectively.

Referring to FIG. 1, the capacitor 200 includes a first electrode 201, a dielectric layer 202, and a second electrode 203. The dielectric layer 202 is located between the first electrode 201 and the second electrode 203; each first electrode 201 fills a corresponding notch 104. The dielectric layer 202 and the second electrode 203 are disposed between two adjacent transistors 140 spaced apart along the second direction.

Referring to FIG. 1, the drain region 103 is in electrical contact with the contact structure 130, and the source region 102 is in electrical contact with the first electrode 201.

Referring to FIG. 1, the first electrode 201 can also serve dually as the source electrode or the drain electrode of the transistor 140 provided in the embodiment of the present disclosure, thereby connecting the transistor 140 and the capacitor 200.

It can be understood that if the ratio of the height of the notch 104 to the width of the notch 104 is relatively large, the dielectric layer 202 and the second electrode 203 can also be disposed within the notch 104 to increase the area of the capacitor 200, thereby increasing the capacitance of the capacitor 200. This is beneficial for reducing the refresh frequency of the 3D DRAM provided in the present disclosure, thus lowering power consumption.

The material of the first electrode 201 and the material of the contact structure 130 may be different or the same, and can be determined based on the performance and manufacturing process requirements of the 3D DRAM provided in the embodiment of the present disclosure. Optionally, the first electrode 201 and the contact structure 130 are made of the same material, and can be formed in the same step during the manufacture of the 3D DRAM provided in the embodiment of the present disclosure, to reduce process steps, improve production yield, and lower costs. Furthermore, the material of the first electrode 201 and the material of the contact structure 130 can be one or more of all metal materials that can be used in semiconductor manufacturing, including copper, aluminum, and tungsten.

Additionally, the dielectric layers 202 of different capacitors 200 spaced apart along the first direction can be separated from each other or can be integrally continuous; the second electrodes 203 of different capacitors 200 spaced apart along the first direction can be separated from each other or can be integrally continuous. The relationship of the dielectric layers 202 of different capacitors 200 spaced apart along the first direction and the relationship of the second electrodes 203 of different capacitors 200 spaced apart along the first direction can be determined based on the area requirements for the capacitors 200 and the manufacturing process, and are not specifically limited in the present disclosure.

Exemplarily, referring to FIG. 1, the dielectric layers 202 of different capacitors 200 spaced apart along the first direction are integrally continuous, and the second electrodes 203 of different capacitors 200 spaced apart along the first direction are integrally continuous. The second dielectric portion 320 is simultaneously disposed between two adjacent capacitors 200 spaced apart along the third direction and between two adjacent contact structures 130 spaced apart along the third direction. In this case, the dielectric layers 202 of different capacitors 200 spaced apart along the first direction are integrally continuous, and the second electrodes 203 of different capacitors 200 spaced apart along the first direction are integrally continuous. It is unnecessary to form insulating layers between the different capacitors 200 spaced apart along the first direction, reducing the volume occupied by insulating layers, which is beneficial for further reducing the size of the memory cells 100 provided in the embodiment of the present disclosure, thereby increasing the storage density of the 3D DRAM provided in the embodiment of the present disclosure. Meanwhile, the integrally continuous second electrodes 203 and integrally continuous dielectric layers 202 allow the dielectric layers 202 of different capacitors 200 to be formed simultaneously and the second electrodes 203 of different capacitors 200 to be formed simultaneously during the manufacture of the 3D DRAM provided in the embodiment of the present disclosure. This reduces the process steps required for separately forming the dielectric layers 202 and second electrodes 203 of different capacitors 200, which is beneficial for reducing costs and improving production yield.

Furthermore, referring to FIG. 1, in different memory cells 100 provided in the embodiment of the present disclosure, the sizes of the transistors 140 can be the same or different, and the sizes of the capacitors 200 can be the same or different, which can be determined based on the performance design for the different memory cells 100. Optionally, in the different memory cells 100 provided in the embodiment of the present disclosure, the sizes of the transistors 140 are the same, and the sizes of the capacitors 200 are the same, such that the different memory cells 100 provided in the embodiment of the present disclosure have the same performance, which is beneficial for electronic systems incorporating the 3D DRAM provided in the embodiment of the present disclosure to perform access operations on the 3D DRAM provided in the embodiment of the present disclosure.

The sizes of other parts of the 3D DRAM provided in the embodiment of the present disclosure are not specifically limited in the embodiment of the present disclosure, provided that requirements for process precision, insulation performance, and other performance criteria are met.

According to a second aspect, the present disclosure further provides a manufacturing method of a 3D DRAM. The manufacturing method of a 3D DRAM is used for manufacturing the 3D DRAM provided in the first aspect. The manufacturing method includes: forming a plurality of memory cells 100 arranged in a three-dimensional array, where the plurality of memory cells 100 arranged in the three-dimensional array include a plurality of memory layers spaced apart along a first direction, each of the memory layers includes a plurality of memory groups spaced apart along a second direction, and each of the memory groups includes a plurality of the memory cells 100 distributed along a third direction; the first direction, the second direction, and the third direction are different from each other; each of the memory cells 100 includes a transistor 140 and a capacitor 200; and forming a dielectric structure configured to isolate the plurality of the memory cells 100, where the dielectric structure includes first dielectric portions 310 respectively located between adjacent ones of the transistors 140 spaced apart along the first direction; the transistors 140 each comprise: a gate 110, a gate dielectric layer 120, a channel region 101, a source region 102, and a drain region 103; a length direction of the channel region 101 is parallel to the second direction, and two sidewalls of the channel region 101 along the length direction are recessed inward relative to sidewalls of the corresponding first dielectric portion 310 to form a notch 104; the source region 102 and the drain region 103 are respectively disposed at two sides along the length direction and cover an inner wall of the notch 104; the gate dielectric layer 120 is located between the gate 110 and the channel region 101, between the gate 110 and the source region 102, and between the gate 110 and the drain region 103.

Specifically, in the manufacturing method provided by the embodiment of the present disclosure, the sequence of forming the memory cells 100 and the dielectric structure is not specifically limited; the memory cells 100 and the dielectric structure can also be formed simultaneously.

Compared with the prior art, the beneficial effects of the manufacturing method of a 3D DRAM provided in the embodiment of the present disclosure are the same as those of the 3D DRAM according to the aforementioned technical solution, and thus will not be repeated here.

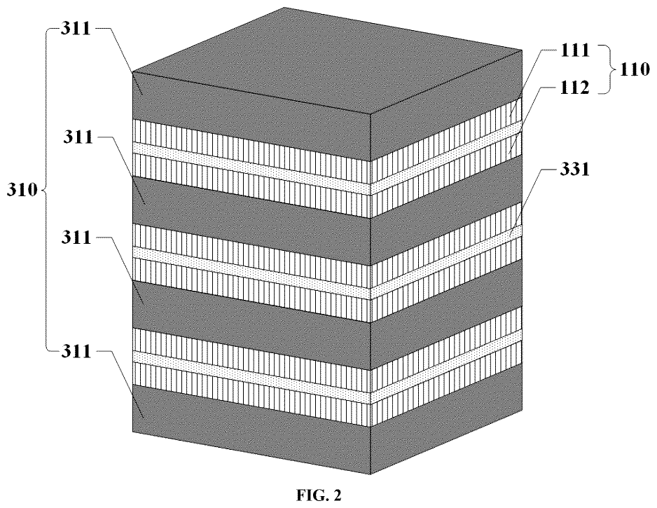

The process of manufacturing the 3D DRAM will be described below with reference to the schematic diagrams of operations shown in FIG. 2 to FIG. 12. Exemplarily, the manufacturing method of the 3D DRAM includes the following steps:

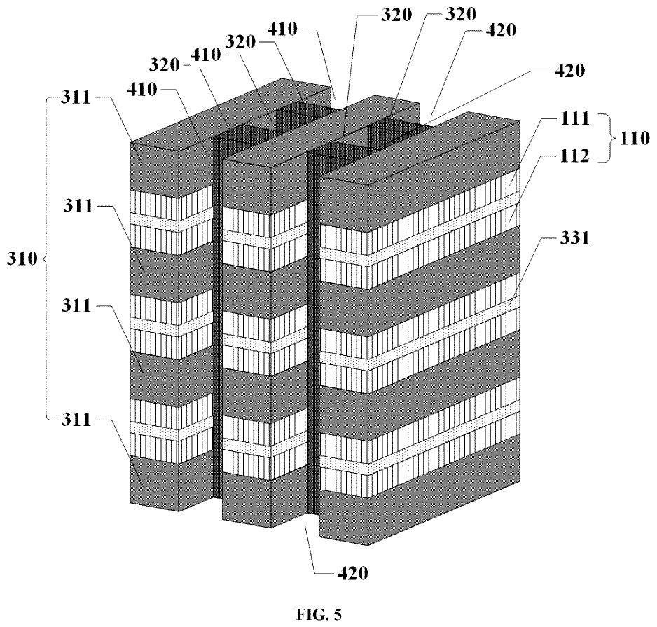

As shown in FIG. 5, a stack structure and second dielectric portions 320 penetrating the stack structure are formed. The stack structure includes a plurality of stack units stacked along the first direction; each of the stack units includes a first dielectric layer 311 and a laminate located on the first dielectric layer 311; the laminate includes a second dielectric layer 331 and the gate 110 that are stacked; a material of the first dielectric layer 311 is different from a material of the second dielectric layer 331; the stack structure is provided with first via groups 410 and second via groups 420 spaced apart along the second direction; the first via groups 410 and the second via groups 420 each include a plurality of vias spaced apart along the third direction; the second dielectric portions 320 are respectively disposed between two adjacent vias along the first direction within a same one of the first via groups 410 and disposed between two adjacent vias along the first direction within a same one of the second via groups 420; the first dielectric portion 310 includes the first dielectric layer 311.

Specifically, the first dielectric layer 311 is used to form the first dielectric portion 310, isolating the memory cells 100 along the first direction. For information such as the material and thickness of the first dielectric layer 311, reference can be made to the relevant description of the first dielectric portion 310, which will not be repeated here.

The laminate of the stack structure includes the stacked second dielectric layer 331 and gate 110. The second dielectric layer 331 serves as a sacrificial layer, pre-occupying positions for the channel region 101 and the gate dielectric layer 120, to facilitate the subsequent formation of the channel region 101 and the gate dielectric layer 120; the second dielectric layer 331 also serves as an isolation layer, insulating and isolating the channel regions 101 and gate dielectric layers 120 of adjacent transistors 140 distributed along the third direction after the subsequent formation of third dielectric portions 332. For the materials and beneficial effects of the second dielectric layer 331, and the first gate 111 and second gate 112 of the gate 110, reference can be made to the relevant description in the first aspect, which will not be repeated here.

Exemplarily, the laminate includes a first gate 111, one second dielectric layer 331, and a second gate 112 disposed along the first direction. The first gate 111 and the second gate 112 constitute the gate 110, which facilitates the subsequent formation of a double-gate transistor structure.

It can be understood that the laminate may also include a single-layer gate 110 and one second dielectric layer 331 to form a conventional transistor 140 or a back-gate transistor. The specific structure of the laminate can be formed according to the requirements for the structure of the transistor 140 in the first aspect, and will not be detailed here.

It should be noted that, along the first direction, the two outermost layers of the stack structure are the first dielectric layers 311, and the thickness of the two outermost first dielectric layers 311 of the stack structure may be greater than that of the first dielectric layers 311 located inside the stack structure, to provide protection for the stack structure and other structures formed subsequently.

Each via in the first via group 410 is used to form a contact structure 130 therein. Each via in the second via group 420 is used to form a capacitor 200 therein.

Each via in the first via group 410 can be a cylindrical hole, a prismatic hole, or in other possible shapes. The size of each via in the first via group 410 is not specifically limited in the embodiment of the present disclosure, as long as the contact structure 130 can be formed within each via of the first via group.

Optionally, a diameter of each via in the first via group 410 can be greater than or equal to 30 nm and less than or equal to 3000 nm. In this case, it is possible to avoid overly stringent requirements on etching and photolithography processes caused by an excessively small via diameter, which would lead to high costs, thus helping to reduce costs. It can also prevent difficulties in uniformly forming the contact structure 130 on the hole wall or even forming the contact structure 130 at all due to an excessively small via diameter. Furthermore, it can avoid the situation where an excessively large via diameter occupies too much area, which would reduce the storage density of the 3D DRAM manufactured according to the embodiment of the present disclosure.

It should be noted that the contact structure 130 formed in each via of the first via group 410 can be disposed as a barrel-shaped structure on the inner wall of the via, forming a barrel-shaped bit line; alternatively, the contact structure 130 can be disposed as a pillar filling each via of the first via group 410, forming a pillar-shaped bit line.

Each via in the second via group 420 can be a cylindrical hole, a prismatic hole, or in other possible shapes. The size of each via in the second via group 420 is not specifically limited in the embodiment of the present disclosure, as long as the capacitor 200 can be formed within each via of the second via group.

A diameter of each via in the second via group 420 is greater than or equal to 50 nm and less than or equal to 5000 nm. In this case, it is possible to avoid overly stringent requirements on etching and photolithography processes caused by an excessively small via diameter, which would lead to high costs, thus helping to reduce costs. It can also prevent the situation where an excessively small via diameter results in a smaller area of the formed capacitor 200, which would reduce the retention time of the capacitor 200 and lead to a higher refresh frequency, thereby increasing power consumption. Thus, it helps to reduce the power consumption of the 3D DRAM manufactured according to the embodiment of the present disclosure. Furthermore, it can avoid the situation where an excessively large via diameter occupies too much area, which would reduce the storage density of the 3D DRAM manufactured according to the embodiment of the present disclosure.

It should be noted that the dielectric layer 202 and the second electrode 203 formed in each via of the second via group 420 can both be disposed as barrel-shaped structures on the inner wall of the via; or the dielectric layer 202 can be disposed as a barrel-shaped structure on the inner wall of the via, and the second electrode 203 can be disposed as a pillar filling each via of the first via group 410.

It needs to be explained that the diameter of the via is defined as the diameter of a cylindrical hole having the same radial cross-sectional area as the via.

Along the third direction, the second dielectric portions 320 separate each via of the first via group 410, and also isolate the contact structures 130 formed in subsequent process steps. Along the third direction, the second dielectric portions 320 separate each via of the second via group 420, and also isolates the capacitors 200 formed in subsequent process steps.

In practical applications, the diameter of each via in the first via group 410 and the diameter of each via in the second via group 420 are not specifically limited in the embodiment of the present disclosure, as long as they meet the performance requirements of the structures disposed within the vias.

In practical applications, the method for forming the stack structure and the second dielectric portions 320 penetrating through the stack structure is not specifically limited in the embodiment of the present disclosure, and can be determined based on the number of memory layers and the manufacturing process of the 3D DRAM provided in the embodiment of the present disclosure.

In one example, the forming the stack structure and the second dielectric portions 320 penetrating through the stack structure may include the following steps:

In the first step, referring to FIG. 2, a stack material layer is formed using a deposition process or an epitaxial process. The stack material layer includes a plurality of stack units that are of the stack structure and stacked along the first direction, where each stack unit includes a first dielectric layer 311 and a laminate located on the first dielectric layer 311.

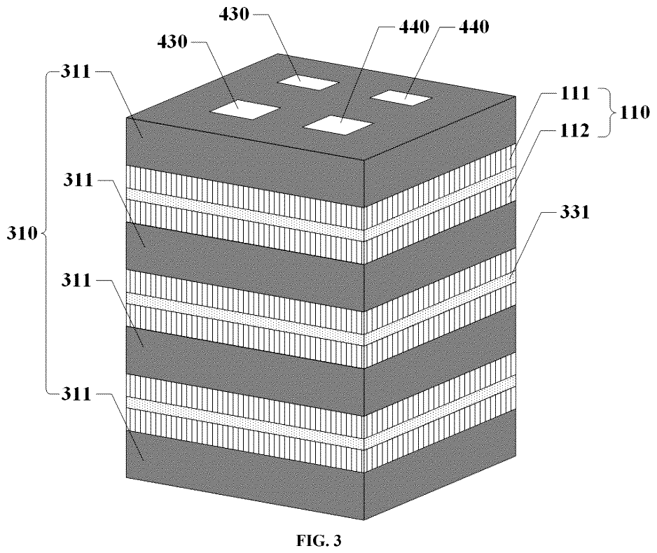

In the second step, referring to FIG. 3, third via groups 430 and fourth via groups 440 penetrating through the stack material layer are formed using processes such as photolithography and etching. An aperture pattern of the third via group 430 is identical to a top pattern of the second dielectric layer 331 disposed between two adjacent vias along the first direction within the same first via group 410; an aperture pattern of the fourth via group 440 is identical to a top pattern of the second dielectric layer 331 disposed between two adjacent vias along the first direction within the same second via group 420. The third via groups 430 and the fourth via groups 440 are formed to facilitate the formation of the second dielectric portions 320 in subsequent steps. The second dielectric portion 320 is used to isolate two adjacent vias along the first direction within the same first via group 410 and to isolate two adjacent vias along the first direction within the same second via group 420. It can be understood that the aperture patterns of the first via group 410 and the third via group 430 that are closest to each other along the second direction are alternately arranged, and the aperture patterns of the second via group 420 and the fourth via group 440 that are closest to each other along the second direction are alternately arranged.

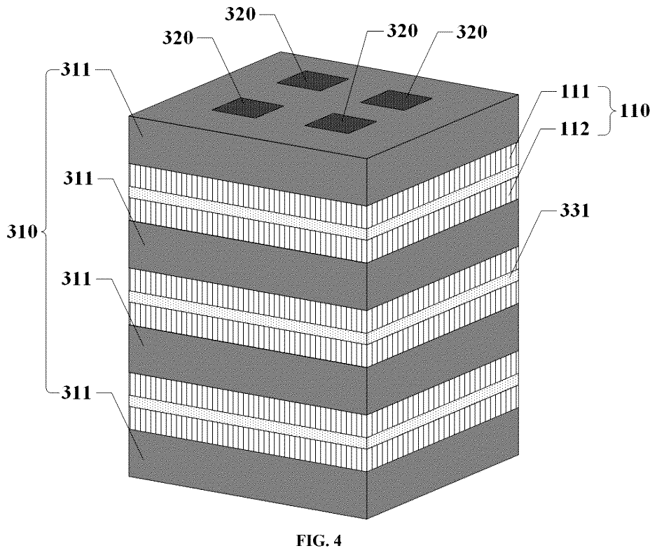

In the third step, referring to FIG. 4, the second dielectric portions 320 filling the third via groups 430 and the fourth via groups 440 are formed using a method such as a deposition process. For the material of the second dielectric portion 320, reference can be made to the corresponding description in the first aspect, which will not be repeated here.

In the fourth step, referring to FIG. 5, the first via groups 410 and the second via groups 420 penetrating through the stack material layer are formed using processes such as photolithography and etching, thereby forming the stack structure.

In another example, the method for forming the stack structure and the second dielectric portions 320 penetrating through the stack structure may also involve first forming a portion of the stack material layer and forming the first via groups 410 and the second via groups 420; then forming another portion of the stack material layer and forming the first via groups 410 and the second via groups 420; and repeating the aforementioned process until the stack structure is finally formed.

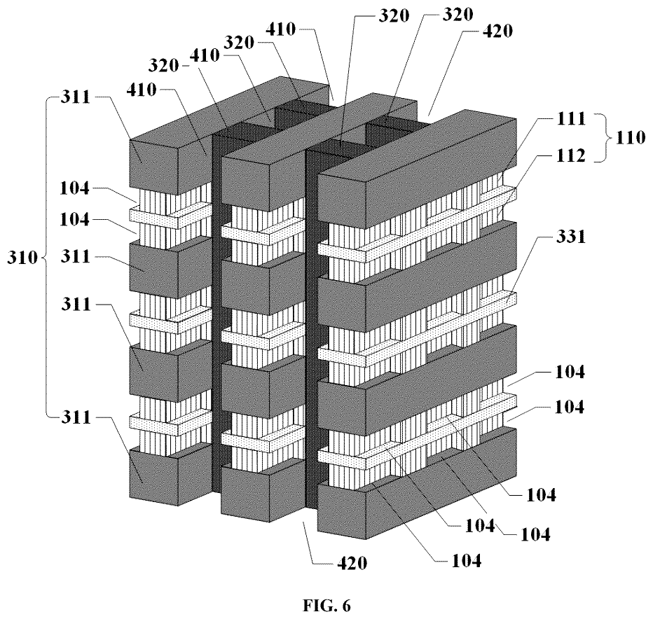

Next, referring to FIG. 6, edge portions of the first gate 111 and the second gate 112 are selectively removed using a process such as selective etching, forming notches 104, and the stack structure is formed. For the dimensions and beneficial effects of the notches 104, reference can be made to the corresponding description in the first aspect, which will not be repeated here.

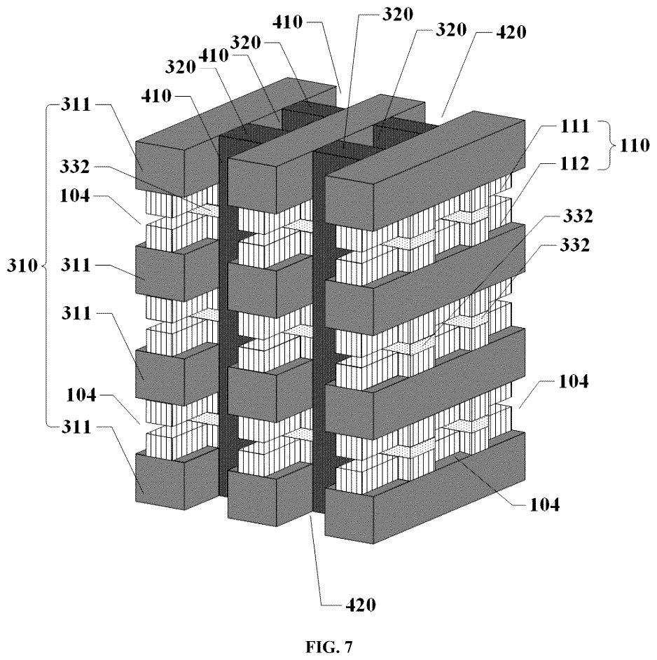

Next, referring to FIG. 7, the second dielectric layers 331 are selectively removed using a process such as selective etching, such that the remaining portions of the second dielectric layers 331 form the third dielectric portions 332, and suspended regions for forming the channel regions 101 are formed. The suspended regions are respectively located between two layers of the third dielectric portions 332 along the first direction, and between two gates of each transistor 140 along the third direction.

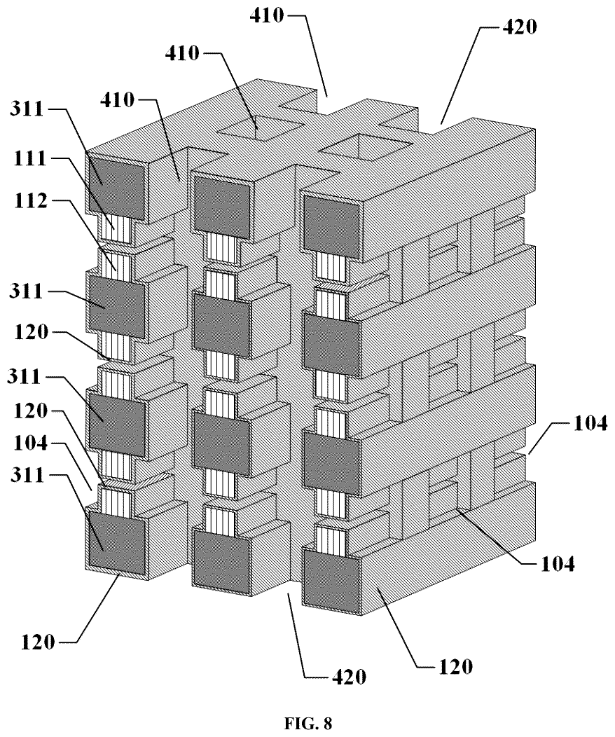

Next, referring to FIG. 8, a gate dielectric layer 120 is deposited over the entire surface of the stack structure using a thin-film deposition process. For the material and the beneficial effects of the gate dielectric layer 120, referring to the corresponding description in the first aspect, which will not be repeated here.

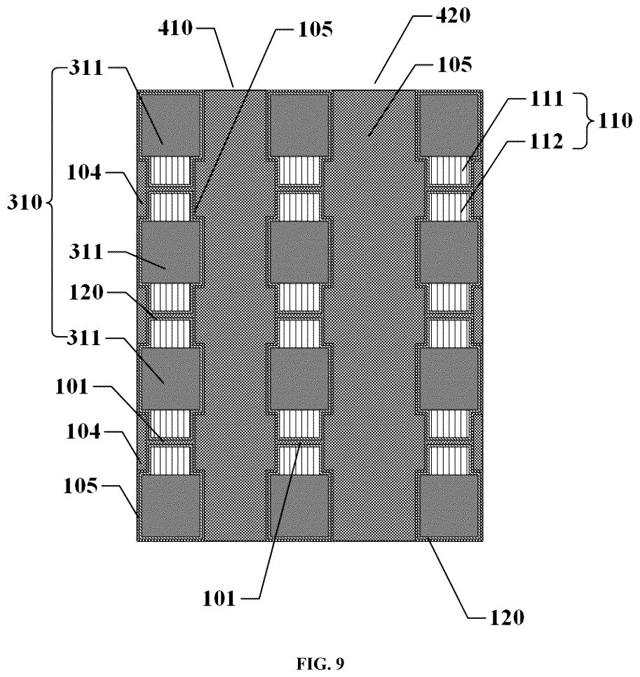

Next, referring to FIG. 9, a channel layer 105 is deposited over the entire surface of the stack structure using a thin-film deposition process. The channel layer 105 completely fills the suspended regions and forms the channel regions 101. For the material and the beneficial effects of the channel layer 105, reference can be made to the corresponding description of the channel region 101 in the first aspect, which will not be repeated here.

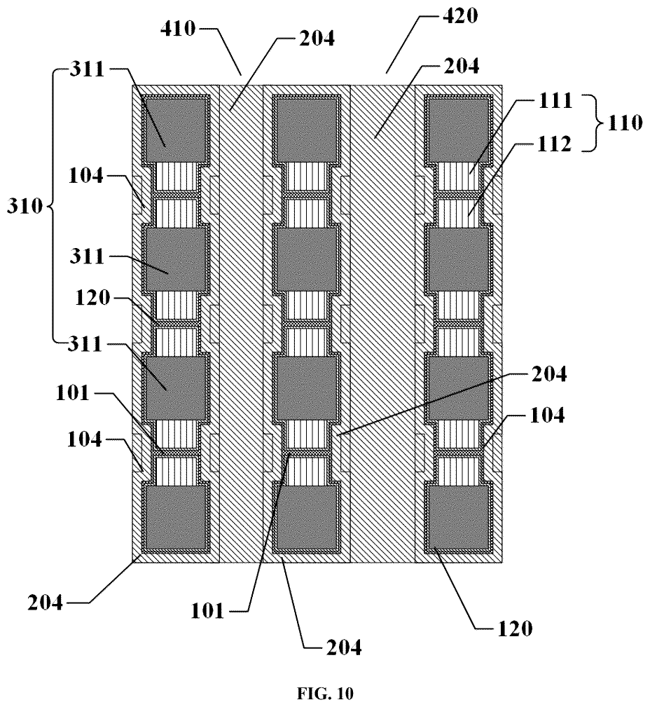

Next, referring to FIG. 10, an electrode layer 204 is deposited over the entire surface of the stack structure using a thin-film deposition process. The electrode layer 204 is processed into the first electrodes 201 and the contact structures 130 in subsequent steps. For the material and the beneficial effects of the electrode layer 204, reference can be made to the corresponding description of the channel region 101 in the first aspect, which will not be repeated here.

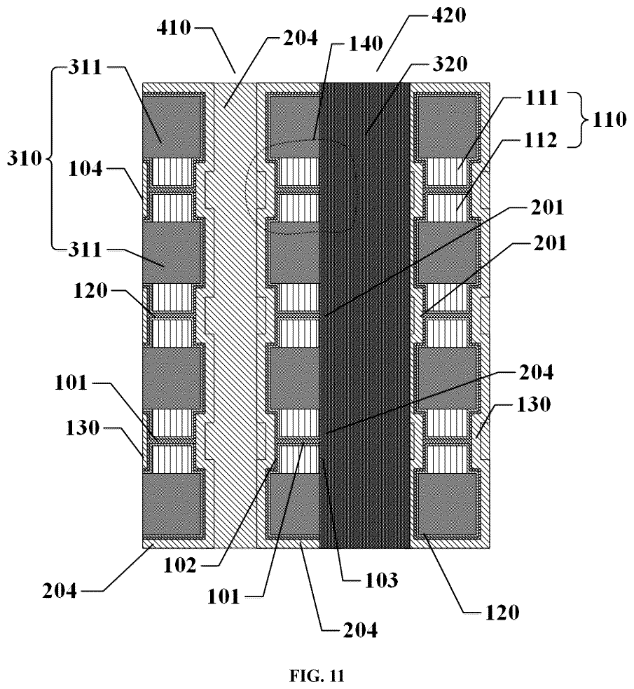

Next, referring to FIG. 11, the channel layer 105, the gate dielectric layer 120, and the electrode layer 204 located within each via of the second via group 420 are removed using processes such as photolithography and etching, retaining only the portions located within the notches 104 adjacent to each via of the second via group 420. The portion of the channel layer 105 located within the notch 104 adjacent to each via of the second via group 420 forms the drain region 103. The portion of the electrode layer 204 located within the notch 104 adjacent to each via of the second via group 420 forms the first electrode 201. The portion of the channel layer 105 located within the notch 104 adjacent to each via of the first via group 410 forms the source region 102. The electrode layer 204 located within each via of the first via group 410 forms the contact structure 130.

It should be noted that the accompanying drawings provided in the embodiment of the present disclosure only illustrate the case where the drain region 103 is electrically connected to the capacitor 200 and the source region 102 is electrically connected to the contact structure 130, but this does not mean that only the above connection relationship is possible. For the specific connection relationship between the source region 102/drain region 103 in the transistor 140 and the contact structure 130 or the capacitor 200, reference can be made to the foregoing description: when the drain region 103 is electrically connected to the capacitor 200, the source region 102 is electrically connected to the contact structure 130.

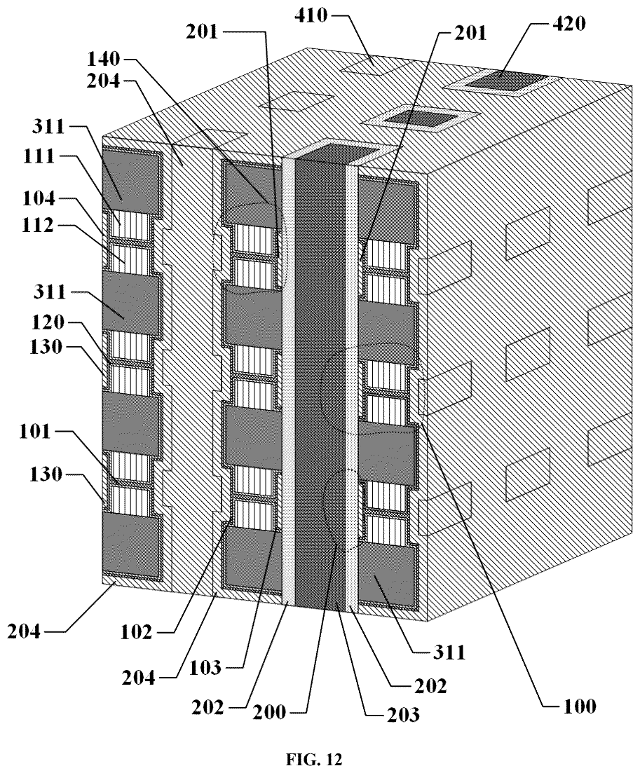

Next, referring to FIG. 12, a dielectric layer 202 is formed within each via of the second via group 420 using a thin-film deposition process.

Next, referring to FIG. 12, a second electrode 203 is formed within each via of the second via group 420 using a thin-film deposition process, where the second electrode 203 is also formed on the dielectric layer 202.

It should be noted that, when the gate dielectric layer 120, the channel layer 105, the electrode layer 204, the dielectric layer 202, and the second electrode 203 are formed using thin-film deposition processes, the same process, such as atomic layer deposition, can be used. This is conducive to continuous processing using the same equipment, thereby reducing damage to the 3D DRAM manufactured according to the embodiment of the present disclosure when the 3D DRAM is transferred between equipment used for different processes, thus improving yield.

With the aforementioned technical solution, referring to FIG. 12, the first dielectric portion 310 includes all of the first dielectric layers 311, and the removed portions of the removed second dielectric layers 331 serve as pre-placeholder structures for the channel regions 101. After removal, the gate dielectric layer 120 covering the periphery of the gate 110 is deposited, followed by deposition of the channel region 101, source region 102, and drain region 103 on the gate dielectric layer 120. In the prior art, during the manufacture of transistors 140, sacrificial layers at both sides of a channel region 101 are first removed, and then a gate dielectric layer 120 and a gate 110 are formed at two sides of the channel region 101 along the first direction and second direction. At this point, the channel region 101 is suspended. Since the channel region 101 is made of a semiconductor material with relatively low structural strength, and given that the memory cells 100 have small geometric dimensions, the channel region 101 made of the semiconductor material with a high aspect ratio along the second direction is prone to collapse, leading to deformation of the transistor 140. This causes performance degradation or even failure of the memory cells 100, which reduces yield. Based on this, in the manufacture of the 3D DRAM in the present disclosure, after the second dielectric layer 331 is selectively etched such that the remaining second dielectric layer 331 forms the third dielectric portion 332, the gate 110 is suspended. Compared to the material of the channel region 101, the material of the gate 110 has higher structural strength and is less likely to collapse, even with a high aspect ratio along the second direction when the memory cells 100 have small geometric dimensions. The manufacturing method of a 3D DRAM provided in the present disclosure can ensure the structural integrity of the transistors 140, thereby ensuring the proper operation and performance stability of the memory cells 100 manufactured by the manufacturing method of a 3D DRAM provided in the present disclosure, and thus improving yield.

Furthermore, referring to FIG. 12, after the second electrode 203 is formed within each via of the second via group 420 using a thin-film deposition process, a planarization process, including chemical mechanical polishing, can be used to polish the outer surface of the 3D DRAM manufactured according to the embodiment of the present disclosure along the first, second, and third directions. This removes the gate dielectric layer 120, the channel layer 105, the electrode layer 204, the dielectric layer 202, and the second electrode 203, ensuring that the plurality of memory cells 100 arranged in a three-dimensional array provided in the embodiment of the present disclosure are mutually insulated at the outer surface of the 3D DRAM.

In the description of the foregoing embodiments the specific features, structures, materials or characteristics may be combined in any suitable manner in any one or more embodiments or examples.

The foregoing descriptions are merely specific implementations of the embodiments of the present disclosure, but the protection scope of the embodiments of the present disclosure is not limited thereto. Any variation or replacement readily figured out by a person skilled in the art within the technical scope disclosed in the embodiments of the present disclosure shall fall within the protection scope of the embodiments of the present disclosure. Therefore, the protection scope of the embodiments of the present disclosure should be subject to the protection scope of the claims.

What is claimed is:

1. A three-dimensional dynamic random access memory, comprising: a plurality of memory cells arranged in a three-dimensional array, and a dielectric structure configured to isolate the plurality of the memory cells, wherein the plurality of memory cells arranged in the three-dimensional array comprise a plurality of memory layers spaced apart along a first direction, each of the memory layers comprises a plurality of memory groups spaced apart along a second direction, and each of the memory groups comprises a plurality of the memory cells distributed along a third direction; the first direction, the second direction, and the third direction are different from each other;
each of the memory cells comprises: a transistor and a capacitor; the dielectric structure comprises first dielectric portions respectively located between adjacent ones of the transistors spaced apart along the first direction;
the transistor comprises: a gate, a gate dielectric layer, a channel region, a source region, and a drain region; a length direction of the channel region is parallel to the second direction, and two sidewalls of the channel region along the length direction are recessed inward relative to sidewalls of a corresponding one of the first dielectric portions to form a notch; the source region and the drain region are respectively disposed at two sides of the channel region along the length direction and cover an inner wall of the notch; the gate dielectric layer is located between the gate and the channel region, between the gate and the source region, and between the gate and the drain region;
and the capacitor is electrically connected to the source region or the drain region of the transistor.

2. The three-dimensional dynamic random access memory according to claim 1, wherein a ratio of a height of the notch to a width of the notch is greater than or equal to 0.1 and less than or equal to 10; the height of the notch is parallel to the first direction, and the width of the notch is parallel to the second direction.

3. The three-dimensional dynamic random access memory according to claim 1, wherein a ratio of a length of the channel region to a thickness of the channel region is greater than or equal to 10 and less than or equal to 1000; a thickness direction of the channel region is parallel to the first direction;
and/or, a ratio of the thickness of the channel region to a width of the notch is greater than or equal to 0.1 and less than or equal to 10; the width of the notch is parallel to the second direction.

4. The three-dimensional dynamic random access memory according to claim 1, wherein a material of the channel region comprises indium gallium zinc oxide;
and/or, the source region, the drain region, and the channel region are integrally continuous.

5. The three-dimensional dynamic random access memory according to claim 1, wherein the gate comprises a first gate and a second gate respectively disposed at two sides of the channel region along the first direction.

6. The three-dimensional dynamic random access memory according to claim 1, further comprising contact structures;
wherein in the source region and the drain region of the transistor, when the source region is electrically connected to the capacitor, the drain region is electrically connected to a corresponding one of the contact structures; or, in the source region and the drain region of the transistor, when the drain region is electrically connected to the capacitor, the source region is electrically connected to a corresponding one of the contact structures; and
the dielectric structure further comprises second dielectric portions and third dielectric portions; the second dielectric portions are respectively located between two adjacent ones of the capacitors spaced apart along the third direction and between two adjacent ones of the contact structures spaced apart along the third direction; and the third dielectric portions are respectively located between two adjacent ones of the transistors spaced apart along the third direction.

7. The three-dimensional dynamic random access memory according to claim 6, wherein the capacitors each comprise a first electrode, a dielectric layer, and a second electrode; the dielectric layer is located between the first electrode and the second electrode; each of the first electrodes fills a corresponding one of the notches; the dielectric layer and the second electrode are disposed between two adjacent ones of the transistors spaced apart along the second direction; and
the dielectric layers in different ones of the capacitors spaced apart along the first direction are integrally continuous, and the second electrodes in different ones of the capacitors spaced apart along the first direction are integrally continuous.
